(19) United States
(12) Patent Application Publication
(10) Pub. No.: US 2026/0173387 A1
(43) Pub. Date: Jun. 18, 2026

(54) SILICON-OXIDE-NITRIDE-OXIDE-SILICON TYPE NON-VOLATILE MEMORY

(71) Applicant: eMemory Technology Inc., Hsin-Chu (TW)

(72) Inventors: Chia-Jung HSU, Hsinchu County (TW); Chun-Hsiao LI, Hsinchu County (TW); Chang-Chun LUNG, Hsinchu County (TW)

(21) Appl. No.: 19/416,244

(22) Filed: Dec. 11, 2025

Related U.S. Application Data
(60) Provisional application No. 63/734,217, filed on Dec. 16, 2024.

(51) Int. Cl. H10B 43/35; G11C 5/06; G11C 16/04; G11C 16/14; G11C 16/26; G11C 16/30; H10D 30/01; H10D 30/69; H10D 62/10

(52) U.S. Cl. CPC H10B 43/35; G11C 5/063; G11C 16/0466; G11C 16/14; G11C 16/26; G11C 16/30; H10D 30/69; H10D 62/124; H10D 30/0413

(57) ABSTRACT

A SONOS type non-volatile memory includes a memory cell array. The memory cell array includes a memory cell area and a non-memory cell area. The connection relationship between SONOS memory cells in the memory cell area are specially designed, and the memory cell array is divided into multiple sections. When the erase action is performed, only one section in the memory cell array is erased, but the other sections are not erased. Furthermore, isolation transistors are provided in the non-memory cell area to isolate the well lines and the bit line. Consequently, the SONOS memory cells can be operated normally.

This application claims the benefit of U.S. provisional application Ser. No. 63/734,217, filed Dec. 16, 2024, the subject matters of which are incorporated herein by references.

### FIELD OF THE INVENTION

The present invention relates to a non-volatile memory, and more particularly to a silicon-oxide-nitride-oxide-silicon (SONOS) type non-volatile memory.

### BACKGROUND OF THE INVENTION

As is well known, non-volatile memories have been widely used in a variety of electronic devices. Generally, a non-volatile memory includes a memory cell array. The memory cell array includes a plurality of memory cells. Each memory cell includes a storage transistor.

When the storage transistor is a silicon-oxide-nitride-oxide-silicon transistor (SONOS transistor), the memory cell is referred to as a silicon-oxide-nitride-oxide-silicon memory cell (SONOS memory cell), and the non-volatile memory is referred to as a SONOS type non-volatile memory. In addition, the SONOS transistor can be referred to as a charge-trap transistor.

### SUMMARY OF THE INVENTION

An embodiment of the present invention provides a silicon-oxide-nitride-oxide-silicon (SONOS) non-volatile memory. The SONOS non-volatile memory includes a memory cell array. The memory cell array is formed on a semiconductor substrate. The memory cell array includes a first row with a plurality of SONOS memory cells, a first isolation transistor, a second row with a plurality of SONOS memory cells and a second isolation transistor. The plurality of SONOS memory cells in the first row are formed in a first well region. The first terminals of the plurality of SONOS memory cells in the first row are electrically connected to a first source line. The second terminals of the plurality of SONOS memory cells in the first row are electrically connected to a first bit line. The control gate terminals of the plurality of SONOS memory cells in the first row are electrically connected to a control line. The select gate terminals of the plurality of SONOS memory cells in the first row are respectively connected to a plurality of word lines. The first isolation transistor is formed in the first well region and located at a first side of the first row. A first drain/source terminal of the first isolation transistor is electrically connected to a first well line. A second drain/source terminal of the first isolation transistor is electrically connected to the first bit line. An isolation gate terminal of the first isolation transistor is electrically connected to an isolation gate line. A body terminal of the first isolation transistor is electrically connected to the first well region. The first well line is electrically connected to the first well region. The plurality of SONOS memory cells in the second row are formed in a second well region. The first terminals of the plurality of SONOS memory cells in the second row are electrically connected to a second source line. The second terminals of the plurality of SONOS memory cells in the second row are electrically connected to a second bit line. The control gate terminals of the plurality of SONOS memory cells in the second row are electrically connected to the control line. The select gate terminals of the plurality of SONOS memory cells in the second row are respectively connected to the plurality of word lines. The second isolation transistor is formed in the second well region and located at a first side of the second row. A first drain/source terminal of the second isolation transistor is electrically connected to a second well line. A second drain/source terminal of the second isolation transistor is electrically connected to the second bit line. An isolation gate terminal of the second isolation transistor is electrically connected to the isolation gate line. A body terminal of the second isolation transistor is electrically connected to the second well region. The second well line is electrically connected to the second well region. The first well region and the second well region are not in contact with each other.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A is a schematic cross-sectional view illustrating the structure of a SONOS memory cell;

FIG. 1B is a schematic circuit diagram illustrating the equivalent circuit of the SONOS memory cell shown in FIG. 1A;

FIG. 2 is a schematic circuit diagram illustrating a memory cell array of a SONOS type non-volatile memory according to an embodiment of the present invention;

FIGS. 3A to 3P schematically illustrate the steps of a method of manufacturing a memory cell array of a SONOS type non-volatile memory according to an embodiment of the present invention;

FIG. 3Q is a schematic equivalent circuit diagram of the memory cell array of the SONOS type non-volatile memory according to the embodiment of the present invention;

FIG. 4A is a schematic circuit diagram illustrating associated bias voltages for performing a program action on the SONOS type non-volatile memory of the present invention;

FIG. 4B is a schematic circuit diagram illustrating associated bias voltages for performing an erase action on the SONOS type non-volatile memory of the present invention;

FIG. 4C is a schematic circuit diagram illustrating associated bias voltages for performing a read action on the SONOS type non-volatile memory of the present invention; and

FIGS. 5A, 5B and 5C schematically illustrate the steps of a variant example of the method of manufacturing the memory cell array of the SONOS type non-volatile memory, in which multiple n-type well region forming steps are performed.

### DETAILED DESCRIPTION OF PREFERRED EMBODIMENTS

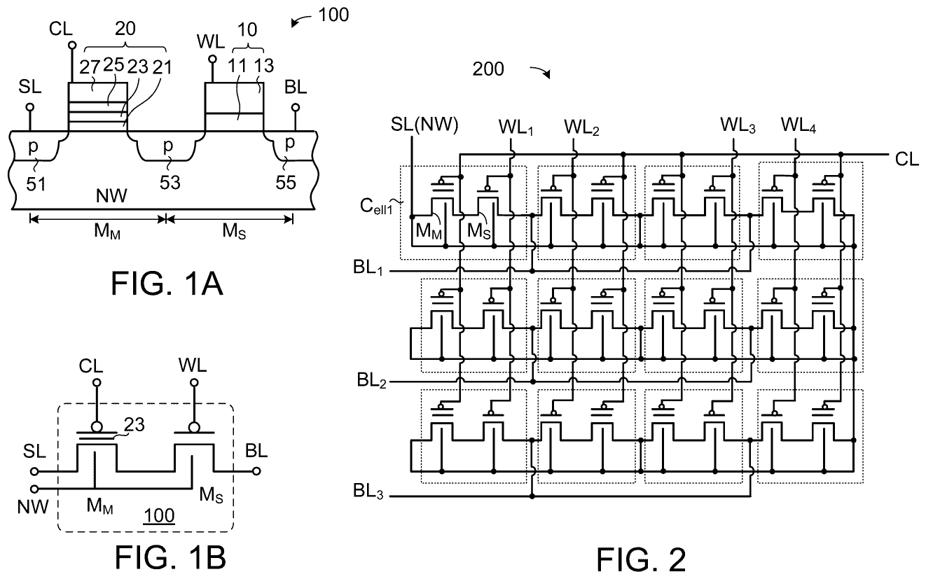

FIG. 1A is a schematic cross-sectional view illustrating the structure of a SONOS memory cell. FIG. 1B is a schematic circuit diagram illustrating the equivalent circuit of the SONOS memory cell shown in FIG. 1A. As shown in FIG. 1A and FIG. 1B, the SONOS memory cell 100 includes a select transistor M_{S} and a storage transistor M_{M}. For illustration, the select transistor M_{S} and the storage transistor M_{M} are p-type transistors.

As shown in FIG. 1A, three p-doped regions 51, 53 and 55 are formed in an N-well region NW. A select gate structure 10 is formed on the surface of the N-well region NW between the p-doped regions 53 and 55. A storage gate structure 20 is formed on the surface of the N-well region NW between the p-doped regions 51 and 53.

The select gate structure 10 includes a gate dielectric layer 11 and a select gate layer 13. The gate dielectric layer 11 covers the surface of the N-well region NW between the p-doped regions 53 and 55. The select gate layer 13 covers the gate dielectric layer 11. For example, the gate dielectric layer 11 is an oxide layer, and the select gate layer 13 is a polysilicon layer. Furthermore, the N-well region NW, the p-doped regions 53 and 55 and the select gate structure 10 are collaboratively formed as a select transistor M_{S}.

The storage gate structure 20 includes an oxide layer 21, a nitride layer 23, an oxide layer 25, and a control gate layer 27. The oxide layer 21 covers the surface of the N-well region NW between the p-doped regions 51 and 53. The nitride layer 23 covers the oxide layer 21. The oxide layer 25 covers the nitride layer 23. The control gate layer 27 covers the oxide layer 25. For example, the control gate layer 27 is a polysilicon layer. The nitride layer 23 can be referred to as a charge storage layer. Furthermore, the N-well region NW, the p-doped regions 51 and 53 and the storage gate structure 20 are collaboratively formed as a storage transistor M_{M}, and the storage transistor M_{M} is a SONOS transistor.

In the SONOS memory cell 100, the p-doped region 51 is electrically connected to a source line SL, the p-doped region 55 is electrically connected to a bit line BL, the control gate layer 27 is electrically connected to a control line CL, and the select gate layer 13 is electrically connected to a word line WL.

As shown in FIG. 1B, the SONOS memory cell 100 includes a select transistor M_{S} and a storage transistor M_{M}. The storage transistor M_{M} includes a nitride layer 23 as a charge storage layer. The first drain/source terminal of the storage transistor M_{M} is electrically connected to a source line SL. The second drain/source terminal of the storage transistor M_{M} is connected to the first drain/source terminal of the select transistor M_{S}. The second drain/source terminal of the select transistor M_{S} is electrically connected to a bit line BL. The select gate terminal of the select transistor M_{S} is electrically connected to the word line WL. The control gate terminal of the storage transistor M_{M} is electrically connected to the control line CL. In addition, the body terminals of the select transistor M_{S} and the storage transistor M_{M} are electrically connected to the N-well region NW.

As mentioned above, the SONOS memory cell 100 includes a first terminal, a second terminal, a select gate terminal and a control gate terminal. The first drain/source terminal of the storage transistor M_{M} is the first terminal of the SONOS memory cell 100, and is electrically connected to the source line SL. The second drain/source terminal of the select transistor M_{S} is the second terminal of the SONOS memory cell 100, and is electrically connected to the bit line BL. The control gate layer 27 of the storage transistor M_{M} is the control gate terminal of the SONOS memory cell 100, and is connected to the control line CL. The select gate layer 13 of the select transistor M_{S} is the select gate terminal of the SONOS memory cell 100, and is electrically connected to the word line WL.

By providing appropriate bias voltages to multiple terminals of the SONOS memory cell 100, a program action, an erase action or a read action can be selectively performed on the SONOS memory cell 100. For example, when carriers are not stored in the nitride layer 23 of the storage transistor M_{M}, the SONOS memory cell 100 is in an erase state. When the program action is performed on the SONOS memory cell 100, carriers are injected into the nitride layer 23 of the storage transistor M_{M}. Consequently, the SONOS memory cell 100 is in a program state. When the erase action is performed on the SONOS memory cell 100, carriers are ejected from the nitride layer 23 of the storage transistor M_{M}. Consequently, the SONOS memory cell 100 is in the erase state. For example, carriers are electrons or holes.

When the read action is performed, the storage state of the SONOS memory cell 100 can be determined according to the magnitude of the read current that is generated by the SONOS memory cell 100. For example, when electrons are stored in the nitride layer 23 of the storage transistor M_{M}, the magnitude of the read current generated by the SONOS memory cell 100 is larger. Consequently, it is determined that the SONOS memory cell 100 is in the program state. When no electrons are stored in the nitride layer 23 of the storage transistor M_{M}, the magnitude of the read current generated by the SONOS memory cell 100 is very low (e.g., nearly zero). Consequently, it is determined that the SONOS memory cell 100 is in the erase state.

In the above embodiment, the SONOS memory cell 100 includes the p-type storage transistor M_{M} and the p-type select transistor M_{S}. In fact, the SONOS memory cell 100 may include an n-type storage transistor M_{M} and an n-type select transistor M_{S}.

Generally, the SONOS transistor can be combined with different types of transistors to form various structures of SONOS memory cells. Furthermore, the connection relationship between SONOS memory cells can be specially designed to form various memory cell arrays and SONOS non-volatile memories.

FIG. 2 is a schematic circuit diagram illustrating a memory cell array of a SONOS type non-volatile memory according to an embodiment of the present invention. The memory cell array 200 includes M×N SONOS memory cells, wherein M and N are positive integers, and M×N is greater than 1. These memory cells are constructed in the same N-well region. The structure of each of the M×N SONOS memory cells is identical to the structure of the memory cell shown in FIG. 1A. In the example of FIG. 2, the memory cell array 200 includes 3×4 SONOS memory cells.

For example, the SONOS memory cell Cₑₗₗ₁ includes a select transistor M_{S} and a storage transistor M_{M}. The first terminal of the SONOS memory cell Cₑₗₗ₁ (i.e., the first drain/source terminal of the storage transistor M_{M}) is electrically connected to a source line SL. The second terminal of the SONOS memory cell Cₑₗₗ₁ (i.e., the second drain/source terminal of the select transistor M_{S}) is electrically connected to a bit line BL1. The control gate terminal of the SONOS memory cell Cₑₗₗ₁ is connected to a control line CL. The select gate terminal of the SONOS memory cell Cₑₗₗ₁ is connected to a word line WL₁. The body terminals of the select transistor M_{S} and the storage transistor M_{M} are connected to the N-well region NW. In addition, the N-well region NW is connected to the source line SL. The connection relationships between other SONOS memory cells and associated conducting lines are similar to the connection relationships between the memory cell Cₑₗₗ₁ and associated conducting lines.

In the memory cell array 200, the control gate terminals of the four SONOS memory cells in the first row are connected to the control line CL, the select gate terminals of the four SONOS memory cells in the first row are respectively connected to the corresponding word lines WL₁˜WL₄, the first terminals of the four SONOS memory cells in the first row are connected to the source line SL, and the second terminals of the four SONOS memory cells in the first row are connected to the bit line BL₁. Similarly, the control gate terminals of the four SONOS memory cells in the second row are connected to the control line CL, the select gate terminals of the four SONOS memory cells in the second row are respectively connected to the corresponding word lines WL₁˜WL₄, the first terminals of the four SONOS memory cells in the second row are connected to the source line SL, and the second terminals of the four SONOS memory cells in the second row are connected to the bit line BL₂. Similarly, the control gate terminals of the four SONOS memory cells in the third row are connected to the control line CL, the select gate terminals of the four SONOS memory cells in the third row are respectively connected to the corresponding word lines WL₁˜WL₄, the first terminals of the four SONOS memory cells in the third row are connected to the source line SL, and the second terminals of the four SONOS memory cells in the first row are connected to the bit line BL₃.

In the memory cell array 200, all SONOS memory cells are connected to the control line CL and the source line SL, and the body terminals of all transistors are connected to the source line SL. Consequently, after an erase operation is completed, all SONOS memory cells in the memory cell array are in the erase state. For example, when the erase operation is performed, the source line SL receives a positive voltage (e.g., +6.5V), the control line CL receives a negative voltage (e.g., −6.5V), all word lines WL1˜WL4 receive an off voltage, and all bit lines BL1˜BL4 receive a ground voltage (0V) or is in a floating state. The difference between the positive voltage and the negative voltage is an erase voltage V_{EE}. In other words, the erase voltage V_{EE}=(+6.5V)−(−6.5V)=13V.

When the erase action is performed, the source line SL and the N-well region NW of all transistors receive the voltage of +6.5V, and the control line CL receives the voltage of −6.5V. Consequently, the in the memory cell array, the voltage difference between the control gate terminal and the body terminal of each storage transistor is the erase voltage V_{EE}. Consequently, the electrons stored in the nitride layer (i.e., the charge storage layer) will be ejected to the N-well region NW, and all SONOS memory cells in the memory cell array are changed to the erase state.

In some special applications, only some of the SONOS memory cells in the memory cell array need to be changed to the erase state when the erase action is performed. That is, not all of the SONOS memory cells need to be changed to the erase state. For example, the memory cell array in the SONOS type non-volatile memory is divided into multiple sections. When the erase action is performed, only the SONOS memory cells in one section will become the erase state, and the SONOS memory cells in the remaining sections will be maintained the original storage state.

Obviously, when the erase action is performed on the memory cell array shown in FIG. 2, all SONOS memory cells will be in the erase state. In other words, the memory cell array structure in FIG. 2 cannot be partially erased.

The present invention provides a SONOS type non-volatile memory. The SONOS type non-volatile memory includes a memory cell array. The memory cell array includes a memory cell area and a non-memory cell area. The memory cell area is composed of a plurality of SONOS memory cells. The non-memory cell area is composed of a plurality of isolation transistors. The structure, the connection relationship and the operation principle of the memory cell array will be described in more detail as follows.

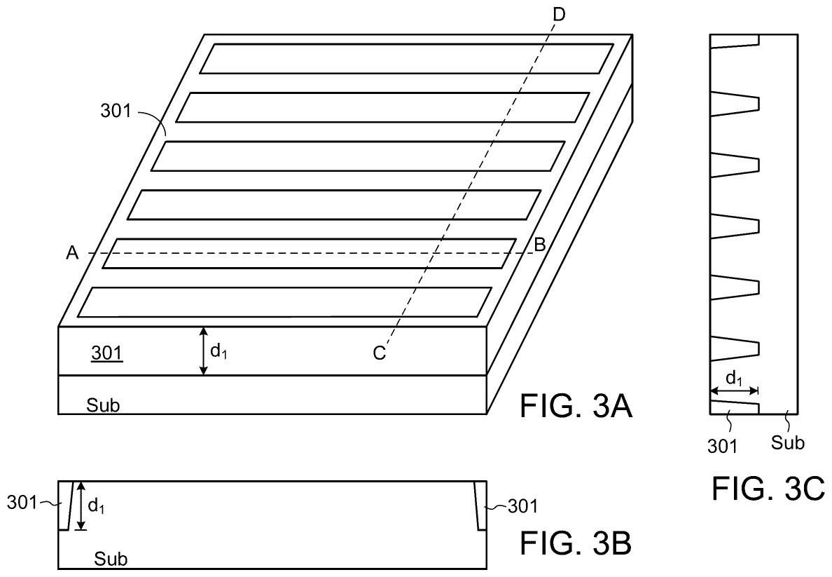

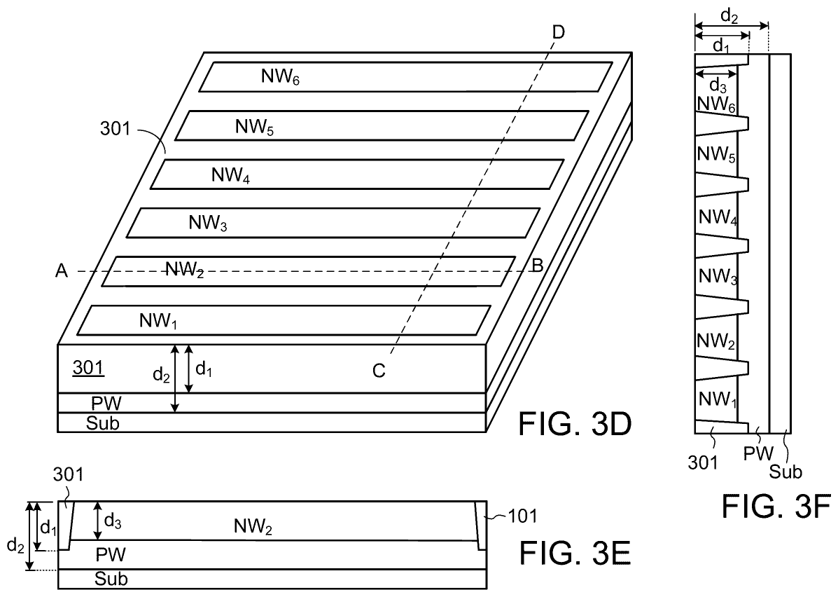

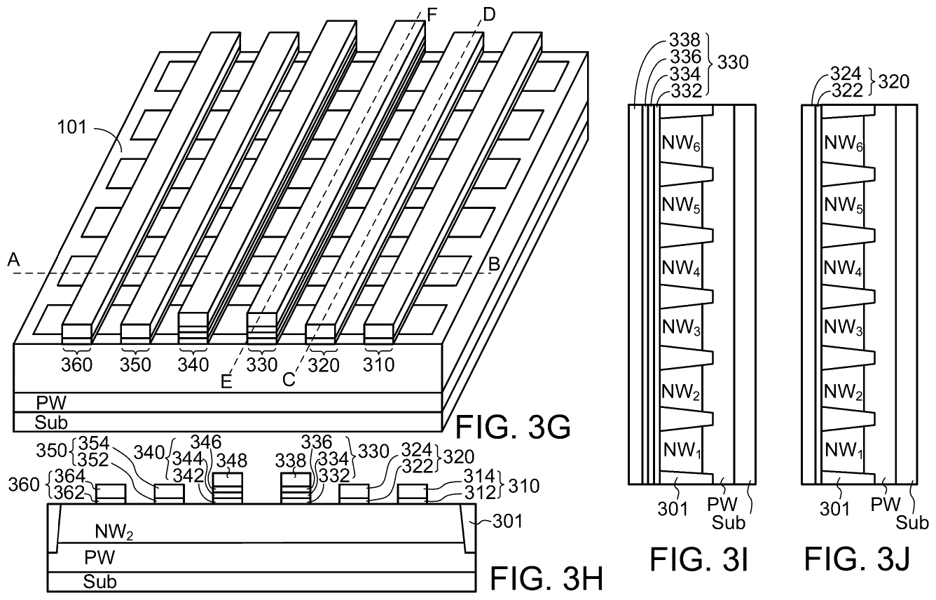

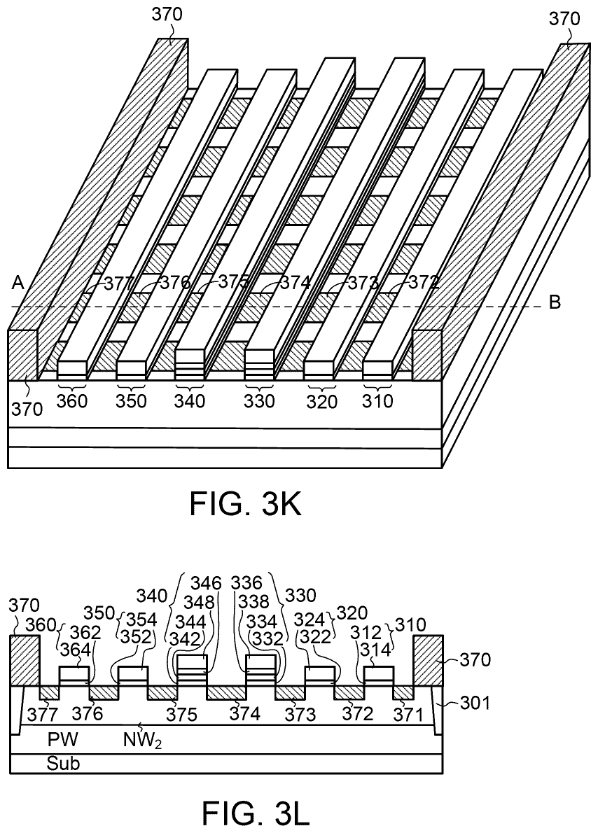

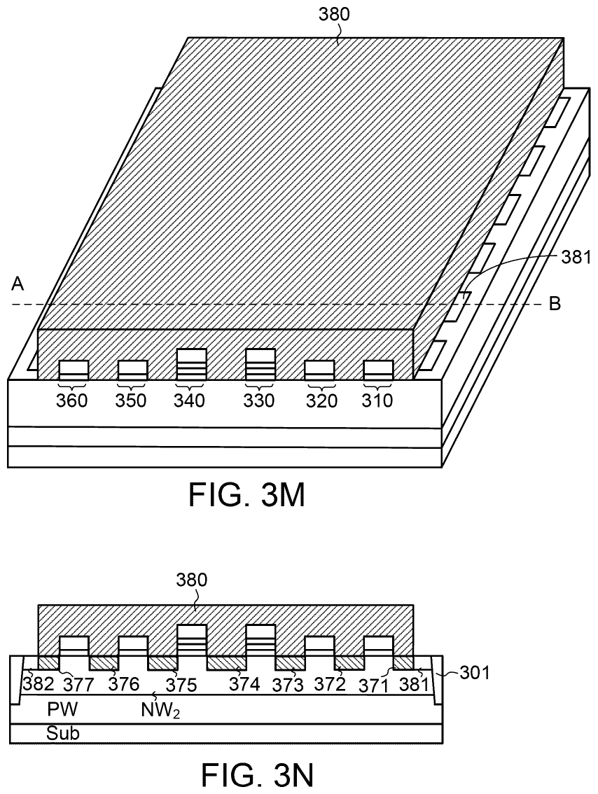

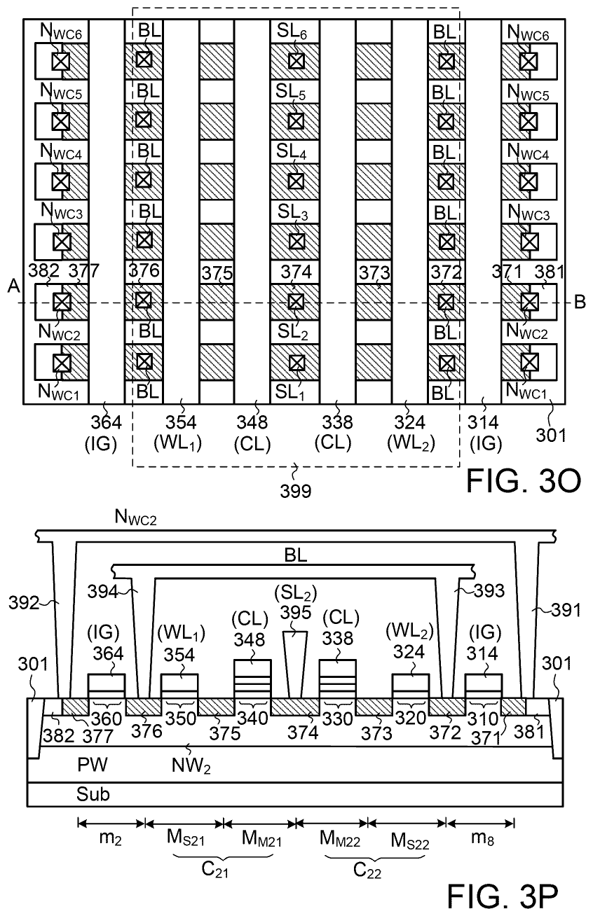

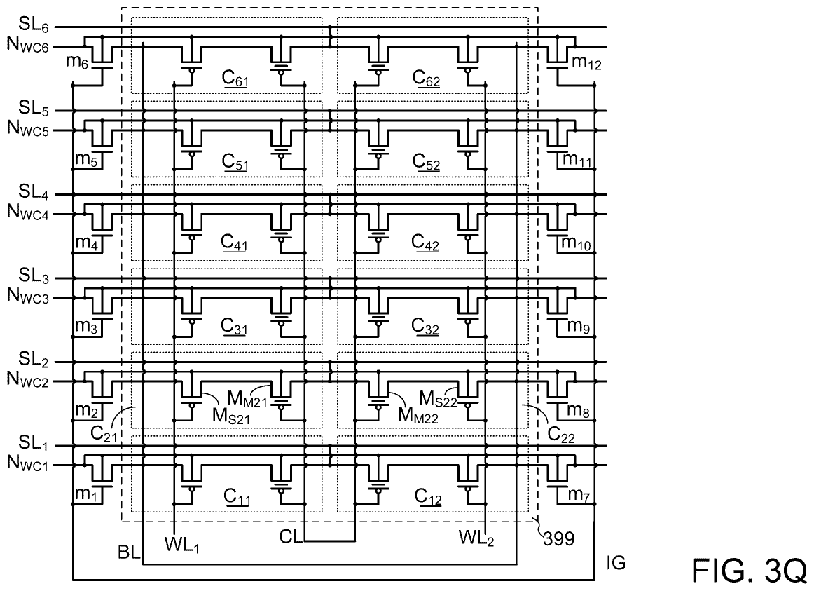

FIGS. 3A to 3P schematically illustrate the steps of a method of manufacturing a memory cell array of a SONOS type non-volatile memory according to an embodiment of the present invention. FIG. 3Q is a schematic equivalent circuit diagram of the memory cell array of the SONOS type non-volatile memory according to the embodiment of the present invention.

Please refer to FIG. 3A. Firstly, a semiconductor substrate Sub is etched, and an isolation structure 301 is formed on the semiconductor substrate Sub. Due to the isolation structure 301, a plurality of regions are defined. For example, the semiconductor substrate Sub is a p-type semiconductor substrate, and the isolation structure 301 is a shallow trench isolation (STI) structure. The isolation structure 301 has a depth d₁. The cross-sectional view of the structure of FIG. 3A taken along the dotted line AB is shown in FIG. 3B. The cross-sectional view of the structure of FIG. 3A taken along the dotted line CD is shown in FIG. 3C.

Please refer to FIGS. 3D, 3E and 3F. Then, a p-type well region forming step and an n-type well region forming step are performed. Firstly, the p-type well region forming step is performed to form a p-type well region PW in the semiconductor substrate Sub, and then the n-type well region forming step is performed to form a plurality of n-type well regions NW₁, NW₂, NW₃, NW₄, NW₅ and NW₆ in the semiconductor substrate Sub. The bottom sides of the n-type well regions NW₁, NW₂, NW₃, NW₄, NW₅ and NW₆ are in contact with the p-type well region PW.

In this embodiment, the p-type well region forming step is performed by using a higher power. Consequently, a depth d₂ of the p-type well region PW is larger than the depth d₁ of the isolation structure 301. Subsequently, the n-type well region forming step is performed by using a lower power. Consequently, a depth d₃ of each of the n-type well regions NW₁, NW₂, NW₃, NW₄, NW₅ and NW₆ is smaller than the depth d₁ of the isolation structure 301. As shown in FIG. 3F, the n-type well regions NW₁, NW₂, NW₃, NW₄, NW₅ and NW₆ are formed in the p-type well region PW, and the n-type well regions NW₁, NW₂, NW₃, NW₄, NW₅ and NW₆ are isolated by the isolation structure 301. That is, the n-type well regions NW₁, NW₂, NW₃, NW₄, NW₅ and NW₆ are separated from each other.

In a variant example, the semiconductor substrate Sub is a p-type semiconductor substrate, and the p-type well region forming step is not performed. That is, only the n-type well region forming step is performed. That is, a plurality of n-type well regions NW₁, NW₂, NW₃, NW₄, NW₅ and NW₆ with the depth d₃ are formed in the surface of the semiconductor substrate Sub. However, the bottom sides of the n-type well regions NW₁, NW₂, NW₃, NW₄, NW₅ and NW₆ are in contact with the semiconductor substrate Sub. Similarly, the depth d₃ of each of the n-type well regions NW₁, NW₂, NW₃, NW₄, NW₅ and NW₆ is smaller than the depth d₁ of the isolation structure 301.

Please refer to FIG. 3G. Then, a plurality of gate structures are formed to cover the top sides of the n-type well regions NW₁, NW₂, NW₃, NW₄, NW₅ and NW₆. The cross-sectional view of the structure of FIG. 3G taken along the dotted line AB is shown in FIG. 3H. The cross-sectional view of the structure of FIG. 3G taken along the dotted line EF is shown in FIG. 3I. The cross-sectional view of the structure of FIG. 3G taken along the dotted line CD is shown in FIG. 3J.

As shown in 3H, the plurality of gate structures includes an isolation gate structure 310, a select gate structure 320, a storage gate structure 330, a storage gate structure 340, a select gate structure 350 and an isolation gate structure 360. The isolation gate structure 310 includes a gate dielectric layer 312 and an isolation gate layer 314. The select gate structure 320 includes a gate dielectric layer 322 and a select gate layer 324. The storage gate structure 330 includes an oxide layer 332, a nitride layer 334, an oxide layer 336 and a control gate layer 338. The storage gate structure 340 includes an oxide layer 342, a nitride layer 344, an oxide layer 346 and a control gate layer 348. The select gate structure 350 includes a gate dielectric layer 352 and a select gate layer 354. The isolation gate structure 360 includes a gate dielectric layer 362 and an isolation gate layer 364.

As shown in FIG. 3G, the surfaces of the n-type well regions NW₁, NW₂, NW₃, NW₄, NW₅ and NW₆ are divided into a plurality of sub-regions by the gate structures 310, 320, 330, 340, 350 and 360.

For succinctness, only the cross-sectional views taken along the dotted lines AB will be described in the following drawings. The cross-sectional views taken along the dotted lines CD and EF are similar to those shown in FIGS. 3J and 3I, and not redundantly described herein.

Then, a mask 370 is formed on two lateral areas of the semiconductor substrate Sub as shown in FIGS. 3K and 3L. In addition, portions of the n-type well regions NW₁, NW₂, NW₃, NW₄, NW₅ and NW₆ on the two lateral areas of the semiconductor substrate Sub are covered by the mask 370. For example, the mask 370 is a photoresist layer. Then, a p-type ion implantation process is performed. Consequently, a plurality of p-type doped region (p-doped region) are formed in the surfaces of the n-type well regions NW₁, NW₂, NW₃, NW₄, NW₅ and NW₆ uncovered by the gate structures 310, 320, 330, 340, 350 and 360 and the mask 370. For example, as shown in FIG. 3L, a plurality of p-doped regions 371, 372, 373, 374, 375, 376 and 377 are formed under the surface of the n-type well region NW₂. Similarly, a plurality of p-doped regions are formed under the surface of each of the n-type well regions NW₁, NW₃, NW₄, NW₅ and NW₆.

Please refer to FIGS. 3M and 3N. After the mask 370 is removed, the regions previously uncovered by the mask 370 is covered with another mask 380. Then, an n-type ion implantation process is performed. Consequently, a plurality of n-type doped region (n-doped region) are formed in the surfaces of the n-type well regions NW₁, NW₂, NW₃, NW₄, NW₅ and NW₆ uncovered by the mask 380. For example, as shown in FIG. 3N, two n-doped regions 381 and 382 are formed under the surfaces of the two sides of the n-type well region NW₂. Similarly, a plurality of n-doped regions are formed under the surfaces of the two sides of each of the n-type well regions NW₁, NW₃, NW₄, NW₅ and NW₆.

Please refer to FIGS. 3O and 3P. After the mask 380 is removed, a connection line forming process is performed. FIG. 3O is a schematic top view illustrating the memory cell array according to the embodiment of the present invention. FIG. 3P is a schematic cross-sectional view illustrating the memory cell array shown in FIG. 3O and taken along the dotted line AB. The middle region of the memory cell array is a memory cell area 399. The two lateral regions of the memory cell array are non-memory cell areas.

Please refer to FIG. 3P. A conducting line 391 is electrically connected to the n-doped region 381 and the p-doped region 371. A conducting line 392 is electrically connected to the n-doped region 382 and the p-doped region 377. The two conducting lines 391 and 392 are connected with each other and collaboratively formed as a well line N_{WC2}. A conducting line 393 is electrically connected to the p-doped region 372. A conducting line 394 is electrically connected to the p-doped region 376. The two conducting lines 393 and 394 are connected with each other and collaboratively formed as a bit line BL. A conducting line 395 is electrically connected to the p-doped region 374 and formed as a source line SL₂. Furthermore, the select gate layer 354 is connected to a word line WL₁, and the select gate layer 324 is connected to a word line WL₂. The two control gate layers 348 and 338 are connected to a control line CL. The two isolation gate layers 314 and 364 are connected to an isolation gate line IG. For example, a contact hole is formed over the n-doped region 381 and the p-doped region 371, and then a metallic material is filled into the contact hole and formed as the conducting line 391. Furthermore, the metallic material forms a butted contact with the n-doped region 381 and the p-doped region 371.

In FIG. 3P, two SONOS memory cell C₂₁ and C₂₂ are shown. The SONOS memory cell C₂₁ includes a select transistor M_{S21} and a storage transistor M_{M21}. The SONOS memory cell C₂₂ includes a select transistor M_{S22} and a storage transistor M_{M22}. The p-doped region 375, the p-doped region 376, the select gate structure 350 and the n-type well region NW₂ are collaboratively formed as the select transistor M_{S21}. The p-doped region 374, the p-doped region 375, the storage gate structure 340 and the n-type well region NW₂ are collaboratively formed as the storage transistor M_{M21}. The p-doped region 372, the p-doped region 373, the select gate structure 320 and the n-type well region NW₂ are collaboratively formed as the select transistor M_{S22}. The p-doped region 373, the p-doped region 374, the storage gate structure 330 and the n-type well region NW₂ are collaboratively formed as the storage transistor M_{M22}.

Furthermore, the n-doped region 382 and the p-doped region 377 are collaboratively formed as a merged doped region. The merged doped region (i.e., the p-doped region 377 and the n-doped region 382), the p-doped region 376, the isolation gate structure 360 and the n-type well region NW₂ are collaboratively formed as an isolation transistor m₂. The merged doped region is served as the first drain/source terminal of the isolation transistor m₂. The p-doped region 376 is served as the second drain/source terminal of the isolation transistor m₂. The isolation gate layer of the isolation gate structure 360 is served as the isolation gate terminal of the isolation transistor m₂. The n-type well region NW₂ is served as the body terminal of the isolation transistor m₂.

The n-doped region 381 and the p-doped region 371 are collaboratively formed as a merged doped region. The merged doped region (i.e., the p-doped region 371 and the n-doped region 381), the p-doped region 372, the isolation gate structure 310 and the n-type well region NW₂ are collaboratively formed as an isolation transistor m₈. The merged doped region is served as the first drain/source terminal of the isolation transistor m₈. The p-doped region 372 is served as the second drain/source terminal of the isolation transistor m₈. The isolation gate layer of the isolation gate structure 310 is served as the isolation gate terminal of the isolation transistor m₈. The n-type well region NW₂ is served as the body terminal of the isolation transistor m₈.

Obviously, the bias voltage received by the well line N_{WC2} is transmitted to the n-type well region NW₂ through the n-doped regions 381 and 382. That is, the body terminals of the transistors M_{S21}, M_{S22}, M_{M21} and M_{M22} in the memory cells C₂₁ and C₂₂ and the body terminals of the isolation transistors m₂ and m₈ are all electrically connected to the well line N_{WC2}.

Since all n-type well regions NW₁˜NW₆ are not connected to each other, other n-type well regions NW₁ and NW₃˜NW₆ also need to receive appropriate bias voltages through corresponding well lines N_{WC1} and N_{WC3}˜N_{WC6}.

Please refer to FIG. 3P again. The first drain/source terminal of the storage transistor M_{M21} is connected to a source line SL₂. The control gate terminal of the storage transistor M_{M21} is connected to the control line CL. The first drain/source terminal of the select transistor M_{S21} is connected to the second drain/source terminal of the storage transistor M_{M21}. The select gate terminal of the select transistor M_{S21} is connected to the word line WL₁. The second drain/source terminal of the select transistor M_{S21} is connected to the bit line BL. The first drain/source terminal of the isolation transistor m₂ is connected to the well line N_{WC2}. The second drain/source terminal of the isolation transistor m₂ is connected to the bit line BL. The isolation gate terminal of the isolation transistor m₂ is connected to the isolation gate line IG. The first drain/source terminal of the storage transistor M_{M22} is connected to the source line SL₂. The control gate terminal of the storage transistor M_{M22} is connected to the control line CL. The first drain/source terminal of the select transistor M_{S22} is connected to the second drain/source terminal of the storage transistor M_{M22}. The select gate terminal of the select transistor M_{S22} is connected to the word line WL₂. The second drain/source terminal of the select transistor M_{S22} is connected to the bit line BL. The first drain/source terminal of the isolation transistor m₈ is connected to the well line N_{WC2}. The second drain/source terminal of the isolation transistor m₈ is connected to the bit line BL. The isolation gate terminal of the isolation transistor m₈ is connected to the isolation gate line IG.

The connection relationships between the other rows of the memory cell array and the corresponding well lines N_{WC1}, N_{WC3}˜N_{WC6} and the corresponding source lines SL₁, SL₃˜SL₆ are similar to the connection relationships shown in FIG. 3P. For example, in the top view of FIG. 3O, the body terminals of all transistors of the memory cells in the first row are connected to the well line N_{WC1}, and the memory cells in the first row are connected to the source line SL₁. The rest may be deduced by analog. Similarly, the body terminals of all transistors of the memory cells in the sixth row are connected to the well line N_{WC6}, and the memory cells in the sixth row are connected to the source line SL₆.

As shown in FIG. 3Q, the memory cell array of the present invention includes a memory cell region 399 and a non-memory cell region. The memory cell region 399 includes M×N SONOS memory cells, wherein M and N are positive integers, and M×N is greater than 1. For example, the memory cell region 399 includes 6×2 SONOS memory cells C₁₁˜C₆₂. The non-memory cell region includes a plurality of isolation transistors m₁˜m₁₂.

The SONOS memory cells C₁₁ and C₁₂ and two isolation transistors m₁ and m₇ in the first row are constructed in the n-type well region NW₁. The isolation transistor m₁ is located at the first side of the first row. The isolation transistor m₇ is located at the second side of the first row. The first terminals of the SONOS memory cells C₁₁ and C₁₂ are electrically connected to the source line SL₁. The second terminals of the SONOS memory cells C₁₁ and C₁₂ are electrically connected to the bit line BL. The control gate terminals of the SONOS memory cells C₁₁ and C₁₂ are electrically connected to the control line CL. The select gate terminals of the SONOS memory cells C₁₁ and C₁₂ are respectively connected to the word lines WL₁ and WL₂. The first drain/source terminals of the isolation transistors m₁ and m₇ are electrically connected to the well line N_{WC1}. The second drain/source terminals of the isolation transistors m₁ and m₇ are electrically connected to the bit line BL. The isolation gate terminals of the isolation transistors m₁ and m₇ are electrically connected to the isolation gate line IG. The body terminals of the isolation transistors m₁ and m₇ are electrically connected to the n-type well region NW₁. The well line N_{WC1} is electrically connected to the n-type well region NW₁.

The SONOS memory cells C₂₁ and C₂₂ and two isolation transistors m₂ and m₈ in the third row are constructed in the n-type well region NW₂. The isolation transistor m₂ is located at the first side of the third row. The isolation transistor m₈ is located at the second side of the second row. The first terminals of the SONOS memory cells C₂₁ and C₂₂ are electrically connected to the source line SL₂. The second terminals of the SONOS memory cells C₂₁ and C₂₂ are electrically connected to the bit line BL. The control gate terminals of the SONOS memory cells C₂₁ and C₂₂ are electrically connected to the control line CL. The select gate terminals of the SONOS memory cells C₂₁ and C₂₂ are respectively connected to the word lines WL₁ and WL₂. The first drain/source terminals of the isolation transistors m₂ and m₈ are electrically connected to the well line N_{WC2}. The second drain/source terminals of the isolation transistors m₂ and m₈ are electrically connected to the bit line BL. The isolation gate terminals of the isolation transistors m₂ and m₈ are electrically connected to the isolation gate line IG. The body terminals of the isolation transistors m₂ and m₈ are electrically connected to the n-type well region NW₂. The well line N_{WC2} is electrically connected to the n-type well region NW₂. The connection relationships of the memory cells C₃₁, C₃₂, C₄₁, C₄₂, C₅₁, C₅₂, C₆₁, C₆₂ and isolation transistors m₃˜m₆, m₉˜m₁₂ in the third row to the six row are similar to those shown in the second row, and not redundantly described herein.

In the above embodiment, the functions of the isolation transistors m₁˜m₁₂ are identical. In a variant example, each row in the memory cell array can be equipped with only one isolation transistor. For example, the memory cell array is equipped with isolation transistors m₁˜m₆ or isolation transistors m₇˜m₁₂ only.

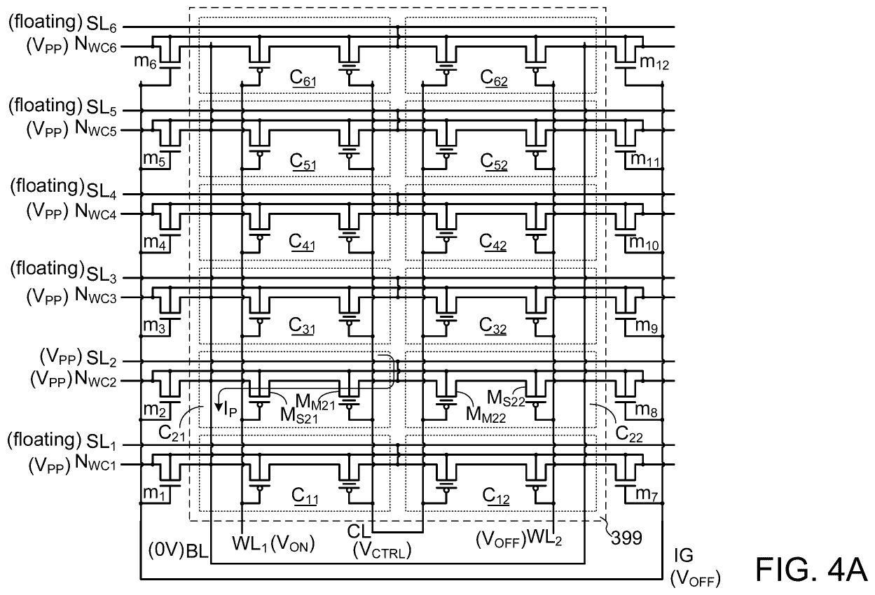

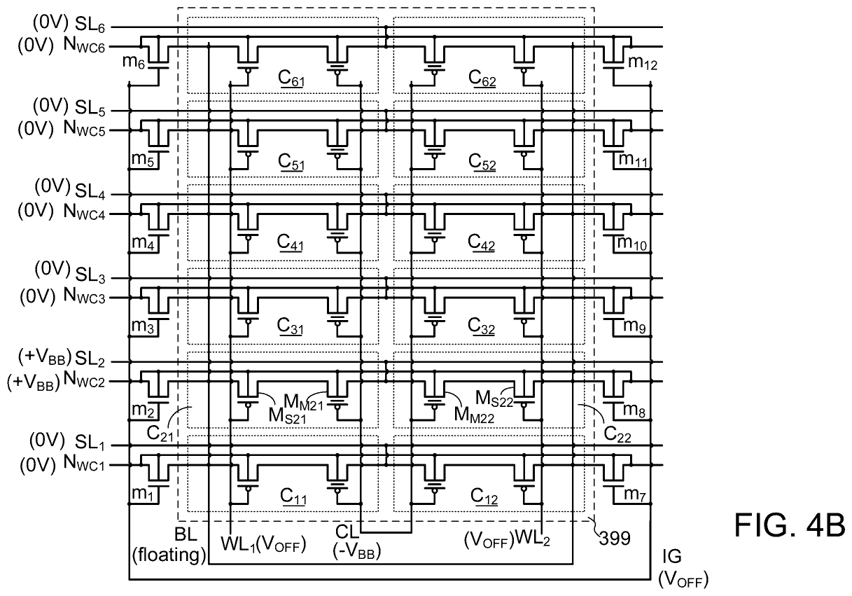

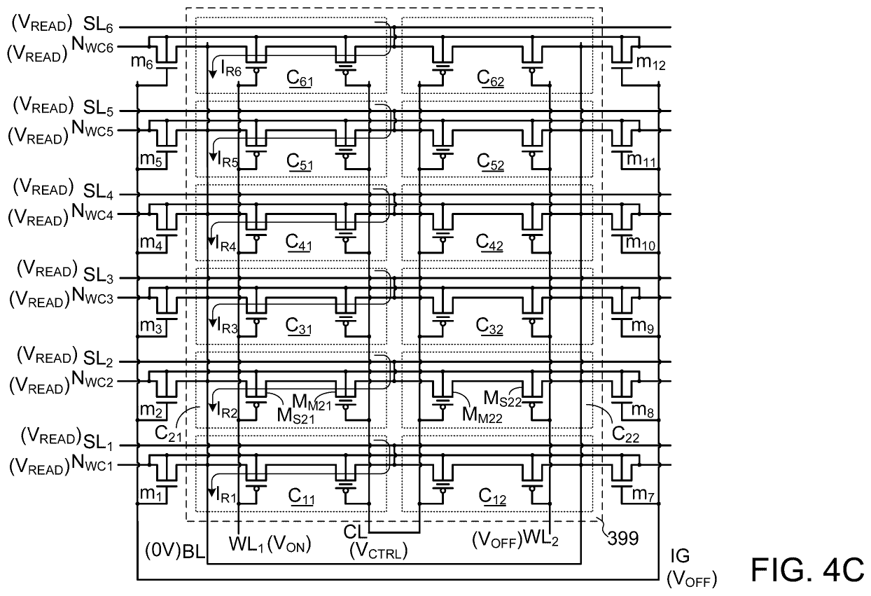

FIG. 4A is a schematic circuit diagram illustrating associated bias voltages for performing a program action on the SONOS type non-volatile memory of the present invention. FIG. 4B is a schematic circuit diagram illustrating associated bias voltages for performing an erase action on the SONOS type non-volatile memory of the present invention. FIG. 4C is a schematic circuit diagram illustrating associated bias voltages for performing a read action on the SONOS type non-volatile memory of the present invention.

In this embodiment, the isolation transistors m₁˜m₁₂ are arranged on both sides of the memory cell array. The purpose is to prevent the bias voltage received by the well lines N_{WC1}˜N_{WC6} from being transmitted to the bit line BL, causing the memory cell array to be unable to perform the program action, the erase action or the read action. That is, when the program action, the erase action or the read action is performed, the isolation transistors m₁˜m₁₂ must be controlled to be in the off state. For example, the isolation transistors m₁˜m₁₂ are p-type transistors, and their threshold voltages are negative. By providing a positive off voltage V_{OFF} to the isolation gate line IG, the isolation transistors m₁˜m₁₂ are turned off.

As shown in FIG. 4A, the SONOS memory cell C₂₁ is determined as a selected memory cell according to the bias voltages, and the program action is performed on the SONOS memory cell C₂₁. When the program action is performed, the off voltage V_{OFF} is provided to the isolation gate line IG. Consequently, the isolation transistors m₁˜m₁₂ are in the off state.

When the program action is performed, a program voltage V_{PP} is provided to the well lines N_{WC1}˜N_{WC6}, an on voltage V_{ON} is provided to the word line WL₁, the off voltage V_{OFF} is provided to the word line WL₂, a ground voltage (0V) is provided to the bit line BL, a control voltage V_{CTRL} is provided to the control line CL, the program voltage V_{PP} is provided to the source line SL₂, and other source lines SL₁ and SL₃˜SL₆ are in the floating state. For example, the on voltage V_{ON} is −1.5V, the off voltage V_{OFF} is a positive voltage, and the off voltage V_{OFF} and the program voltage V_{PP} are 5V. In addition, the control voltage V_{CTRL} is a fixed positive voltage or a gradually ramped positive voltage.

In the SONOS memory cell C₂₁, the select transistor M_{S21} is turned on, and a program current I_{P} generated by the SONOS memory cell C₂₁ flows from the source line SL₂ to the bit line BL. When the program current I_{P} flows through the channel region of the storage transistor M_{M21}, electrons are injected into the charge storage layer. Consequently, the SONOS memory cell C₂₁ is in a program state. Furthermore, except for the SONOS memory cell C₂₁, the other SONOS memory cells in the memory cell array cannot generate the program current. Consequently, the storage state is not changed.

As shown in FIG. 4B, the SONOS memory cells C₂₁ and C₂₂ in the second row are controlled to be in the erase state, and the storage states of the SONOS memory cells in other rows of the memory cell array are not changed. When the erase action is performed, the off voltage V_{OFF} is provided to the isolation gate line IG. Consequently, the isolation transistors m₁˜m₁₂ are in the off state.

When the erase action is performed, a positive voltage +V_{BB} is provided to source line SL₂, the ground voltage (0V) is provided to other source lines SL₁ and SL₃˜SL₆, the positive voltage +V_{BB} is provided to the well line N_{WC2}, the ground voltage (0V) is provided to other well lines N_{WC1} and N_{WC3}˜N_{WC6}, a negative voltage −V_{BB} is provided to the control line CL, the off voltage V_{OFF} is provided to the word lines WL₁ and WL₂, and the bit line BL is in the floating state.

The difference between the positive voltage +V_{BB} and the negative voltage −V_{BB} is an erase voltage V_{EE}. For example, the positive voltage +V_{BB} is +6V and the negative voltage −V_{BB} is −6V. Consequently, the erase voltage V_{EE}=(+6V)−(−6V)=12V. In the SONOS memory cells C₂₁ and C₂₂ of the second row, the voltage difference between the control gate terminals of the storage transistors M_{M21} and M_{M22} and the n-type well region NW₂ is the erase voltage V_{EE}. Consequently, the electrons stored in the charge storage layer of the storage transistors M_{M21} and M_{M22} will be ejected to the n-type well region NW₂, and the SONOS memory cells C₂₁ and C₂₂ in the second row are in the erase state. Furthermore, the SONOS memory cells in other rows of the memory cell array do not receive the erase voltage V_{EE}, and thus their storage states are not changed.

As shown in FIG. 4C, the storage states of the SONOS memory cells C₁₁˜C₆₁ are determined according to the bias voltages. When the read action is performed, the off voltage V_{OFF} is provided to the isolation gate line IG. Consequently, the isolation transistors m₁˜m₁₂ are in the off state.

When the read action is performed, a read voltage V_{READ} is provided to the well lines N_{WC1}˜N_{WC6}, the read voltage V_{READ} is provided to the source lines SL₁˜SL₆, the on voltage V_{ON} is provided to the word line WL₁, the off voltage V_{OFF} is provided to the word line WL₂, the ground voltage (0V) is provided to the bit line BL, and the control voltage V_{CTRL} is provided to the control line CL. For example, the on voltage V_{ON} is −1.5V, the off voltage V_{OFF} is a positive voltage, and each of the off voltage V_{OFF}, the control voltage V_{CTRL} and the read voltage V_{READ} is 1.5V. Consequently, the select transistors in the SONOS memory cells C₁₁˜C₆₁ are turned on. In addition, the read currents I₁˜I₆ generated by the SONOS memory cells C₁₁˜C₆₁ flow from the source lines SL₁˜SL₆ to the bit line BL.

In the SONOS memory cell C₂₁, the read current I2 flows from the source line SL₂ to the bit line BL. In case that electrons are stored in the charge storage layer of the storage transistor M_{S21} and the memory cell is in the program state, the read current I₂ is relatively larger. Whereas, in case that no electrons are stored in the charge storage layer of the storage transistor MS21 and the memory cell is in the erase state, the read current I₂ is relatively smaller and nearly zero. In other words, the storage state of the SONOS memory cell C₂₁ can be determined according to the magnitude of the read current I₂ on the source line SL₂. Similarly, the storage states of SONOS memory cells C₁₁ and C₃₁˜C₆₁ can be determined according to the magnitudes of the read currents I₁ and I₃˜I₆.

From the above descriptions, the present invention provides a SONOS type non-volatile memory. The memory cell array of the SONOS type non-volatile memory includes a memory cell area and a non-memory cell area. The connection relationship between SONOS memory cells in the memory cell area are specially designed, and the memory cell array is divided into multiple sections. When the erase action is performed, only one section in the memory cell array is erased, but the other sections are not erased. Furthermore, isolation transistors are provided in the non-memory cell area to isolate the well lines N_{WC1}˜N_{WC6} and the bit line BL. Consequently, the SONOS memory cells can be operated normally.

The manufacturing process of forming the memory cell array of the present invention can be further modified. For example, in a variant example, multiple n-type well region forming steps are performed.

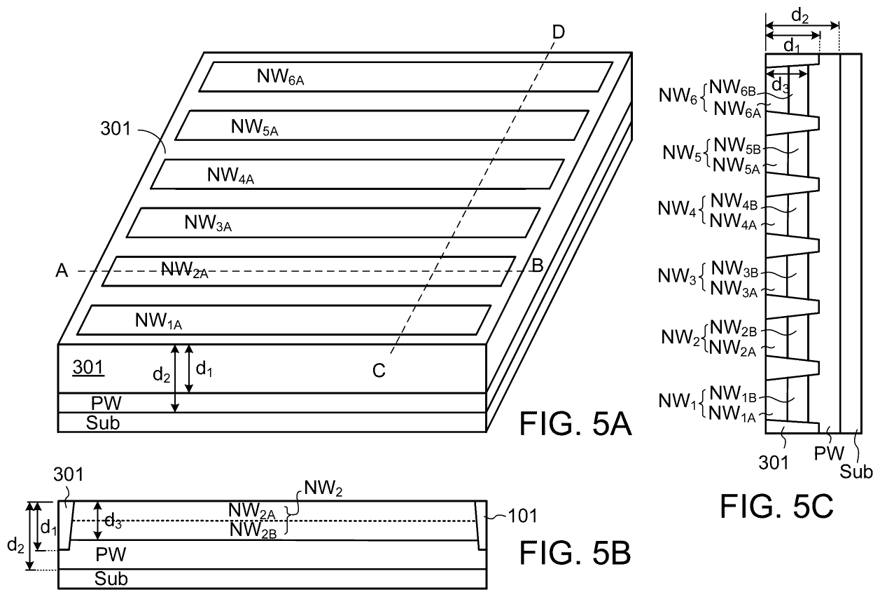

FIGS. 5A, 5B and 5C schematically illustrate the steps of a variant example of the method of manufacturing the memory cell array of the SONOS type non-volatile memory, in which multiple n-type well region forming steps are performed. By controlling the power strength and performing multiple n-type well region forming steps, two n-type sub-well regions NW_{1A} and NW_{1B} are formed and collaboratively formed as an n-type well region NW₁ with the depth d₃. The sub-well region NW_{1B} is arranged between the sub-well region NW_{1A} and the p-type well region PW. Similarly, two n-type sub-well regions NW_{2A} and NW_{2B} are formed and collaboratively formed as an n-type well region NW₂ with the depth d₃. Similarly, two n-type sub-well regions NW_{3A} and NW_{3B} are formed and collaboratively formed as an n-type well region NW₃ with the depth d₃. Similarly, two n-type sub-well regions NW_{4A} and NW_{4B} are formed and collaboratively formed as an n-type well region NW₄ with the depth d₃. Similarly, two n-type sub-well regions NW_{5A} and NW_{5B} are formed and collaboratively formed as an n-type well region NW₅ with the depth d₃. Similarly, two n-type sub-well regions NW_{6A} and NW_{6B} are formed and collaboratively formed as an n-type well region NW₆ with the depth d₃.

It is noted that numerous modifications and alterations may be made while retaining the teachings of the present invention.

For example, the structure of the isolation transistor is modified. As mentioned above in FIG. 3P, the merged doped region (i.e., the p-doped region 377 and the n-doped region 382), the p-doped region 376, the isolation gate structure 360 and the n-type well region NW₂ are collaboratively formed as an isolation transistor m₂, and the well line N_{WC2} is electrically connected to the p-doped region 377 and the n-doped region 382. In a variant example, the well line N_{WC2} is electrically connected to the n-doped region 382 only, but is not electrically connected to the p-doped region 377. Alternatively, the isolation transistor m₂ is equipped with the n-doped region 382 only, but is not equipped with the p-doped region 377. In addition, the well line N_{WC2} is electrically connected to the n-doped region 382.

In the embodiment of FIG. 3Q, the memory cell region 399 includes 6×2 SONOS memory cells. When the erase action is performed, two SONOS memory cells in each row are in the erase state. That is, each section of the memory cell array contains two SONOS memory cells.

In some other embodiments, some of the well lines N_{WC1}˜N_{WC6} are connected with each other according to the size of the section, and thus the number of SONOS memory cells in each section is increased. For example, the well lines N_{WC1} and N_{WC2} in the memory cell array are connected with each other, the well lines N_{WC3} and N_{WC4} in the memory cell array are connected with each other, and the well lines N_{WC5} and N_{WC6} in the memory cell array are connected with each other. Consequently, each section in the memory cell array contains four SONOS memory cells. When the erase action is performed, the four SONOS memory cells in one section are in the erase state, and the storage states of the SONOS memory cells in the other sections are not changed.

In the above embodiments, the transistors in the memory cell array are p-type transistors. In case that the transistors in the memory cell array are n-type transistors, the purpose of the present invention is achievable according to the concept of the present invention.

In the above embodiments, the SONOS memory cells C₁₁˜C₆₂ in the memory cell array are connected to the same bit line BL. In a variant example, different rows of SONOS memory cells are connected to different bit lines. By providing appropriate bias voltages, the program action, the erase action or the read action can be selectively performed.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A silicon-oxide-nitride-oxide-silicon (SONOS) non-volatile memory comprising a memory cell array, the memory cell array being formed on a semiconductor substrate and comprising:
a first row comprising a plurality of SONOS memory cells, which are formed in a first well region, wherein first terminals of the plurality of SONOS memory cells in the first row are electrically connected to a first source line, second terminals of the plurality of SONOS memory cells in the first row are electrically connected to a first bit line, control gate terminals of the plurality of SONOS memory cells in the first row are electrically connected to a control line, and select gate terminals of the plurality of SONOS memory cells in the first row are respectively connected to a plurality of word lines;
a first isolation transistor formed in the first well region and located at a first side of the first row, wherein a first drain/source terminal of the first isolation transistor is electrically connected to a first well line, a second drain/source terminal of the first isolation transistor is electrically connected to the first bit line, an isolation gate terminal of the first isolation transistor is electrically connected to an isolation gate line, and a body terminal of the first isolation transistor is electrically connected to the first well region, wherein the first well line is electrically connected to the first well region;
a second row comprising a plurality of SONOS memory cells, which are formed in a second well region, wherein first terminals of the plurality of SONOS memory cells in the second row are electrically connected to a second source line, second terminals of the plurality of SONOS memory cells in the second row are electrically connected to a second bit line, control gate terminals of the plurality of SONOS memory cells in the second row are electrically connected to the control line, and select gate terminals of the plurality of SONOS memory cells in the second row are respectively connected to the plurality of word lines; and
a second isolation transistor formed in the second well region and located at a first side of the second row, wherein a first drain/source terminal of the second isolation transistor is electrically connected to a second well line, a second drain/source terminal of the second isolation transistor is electrically connected to the second bit line, an isolation gate terminal of the second isolation transistor is electrically connected to the isolation gate line, and a body terminal of the second isolation transistor is electrically connected to the second well region, wherein the second well line is electrically connected to the second well region,
wherein the first well region and the second well region are not in contact with each other.

2. The SONOS type non-volatile memory as claimed in claim 1, further comprising a third isolation transistor, wherein the third isolation transistor is formed in the first well region and located at a second side of the first row, a first drain/source terminal of the third isolation transistor is electrically connected to the first well line, a second drain/source terminal of the third isolation transistor is electrically connected to the first bit line, an isolation gate terminal of the third isolation transistor is electrically connected to the isolation gate line, and a body terminal of the third isolation transistor is electrically connected to the first well region, wherein the first well line is electrically connected to the first well region.

3. The SONOS type non-volatile memory as claimed in claim 1, wherein the first isolation transistor comprises:
a first n-type doped region formed in a surface of the first well region, wherein the first well region is a first n-type well region;
a first p-type doped region formed in the surface of the first n-type well region; and
a first isolation gate structure formed over the surface of the first n-type well region, and arranged between the first n-type doped region and the first p-type doped region,
wherein the first p-type doped region is electrically connected to the first bit line, the first n-type doped region is electrically connected to the first well region, and an isolation gate layer of the first isolation gate structure is electrically connected to the isolation gate line.

4. The SONOS type non-volatile memory as claimed in claim 3, wherein the first isolation transistor further comprises a second p-type doped region, wherein the second p-type doped region is formed in the surface of the first n-type well region and arranged between the first n-type doped region and the first isolation gate structure, and the first n-type doped region and the second p-type doped region are collaboratively formed as a merged doped region.

5. The SONOS type non-volatile memory as claimed in claim 4, wherein the second p-type doped region is electrically connected to the first well line.

6. The SONOS type non-volatile memory as claimed in claim 1, further comprising an isolation structure, wherein the isolation structure is formed on the semiconductor substrate, the first well region is located beside a first side of the isolation structure, the second well region is located beside a second side of the isolation structure, and first well region and the second well region are not in contact with each other.

7. The SONOS type non-volatile memory as claimed in claim 6, wherein the isolation structure has a first depth, each of the first well region and the second well region has a second depth, and the first depth is larger than the second depth.

8. The SONOS type non-volatile memory as claimed in claim 7, wherein the first well region is divided into a first sub-well region and a second sub-well region, and the first sub-well region and the second sub-well region are collaboratively formed as the first well region with the second depth, wherein the second well region is divided into a third sub-well region and a fourth sub-well region, and the third sub-well region and the fourth sub-well region are collaboratively formed as the second well region with the second depth.

9. The SONOS type non-volatile memory as claimed in claim 6, wherein a first SONOS memory cell of the plurality of SONOS memory cells in the first row comprises:
a first p-type doped region formed in a surface of the first well region, wherein the first well region is a first n-type well region;
a second p-type doped region formed in the surface of the first n-type well region;
a third p-type doped region formed in the surface of the first n-type well region;
a first storage gate structure formed on the surface of the first n-type well region, and arranged between the first p-type doped region and the second p-type doped region; and
a first select gate structure formed on the surface of the first n-type well region, and arranged between the second p-type doped region and the third p-type doped region,
wherein the first storage gate structure comprises a first oxide layer, a first nitride layer, a second oxide layer and a first control gate layer, wherein the first oxide layer covers the surface of the first n-type well region, the first nitride layer covers the first oxide layer, the second oxide layer covers the first nitride layer, and the first control gate layer covers the second oxide layer,
wherein the first p-type doped region is electrically connected to the first source line, the third p-type doped region is electrically connected to the first bit line, the first control gate layer of the first storage gate structure is electrically connected to the control line, and a first select gate layer of the first select gate structure is electrically connected to a first word line of the plurality of word lines.

10. The SONOS type non-volatile memory as claimed in claim 9, wherein a second SONOS memory cell of the plurality of SONOS memory cells in the second row comprises:
a fourth p-type doped region formed in a surface of the second well region, wherein the second well region is a second n-type well region;
a fifth p-type doped region formed in the surface of the second n-type well region;
a sixth p-type doped region formed in the surface of the second n-type well region;
a second storage gate structure formed on the surface of the second n-type well region, and arranged between the fourth p-type doped region and the fifth p-type doped region; and
a second select gate structure formed on the surface of the second n-type well region, and arranged between the fifth p-type doped region and the sixth p-type doped region,
wherein the second storage gate structure comprises a third oxide layer, a second nitride layer, a fourth oxide layer and a second control gate layer, wherein the third oxide layer covers the surface of the second n-type well region, the second nitride layer covers the third oxide layer, the fourth oxide layer covers the second nitride layer, and the second control gate layer covers the fourth oxide layer,
wherein the fourth p-type doped region is electrically connected to the second source line, the sixth p-type doped region is electrically connected to the second bit line, the second control gate layer of the second storage gate structure is electrically connected to the control line, and a second select gate layer of the second select gate structure is electrically connected to the first word line.

11. The SONOS type non-volatile memory as claimed in claim 1, further comprising:
a third row comprising a plurality of SONOS memory cells, which are formed in a third well region, wherein first terminals of the plurality of SONOS memory cells in the third row are electrically connected to a third source line, second terminals of the plurality of SONOS memory cells in the third row are electrically connected to a third bit line, control gate terminals of the plurality of SONOS memory cells in the third row are electrically connected to the control line, and select gate terminals of the plurality of SONOS memory cells in the third row are respectively connected to the plurality of word lines; and
a third isolation transistor formed in the third well region and located at a first side of the third row, wherein a first drain/source terminal of the third isolation transistor is electrically connected to the first well line, a second drain/source terminal of the third isolation transistor is electrically connected to the third bit line, an isolation gate terminal of the third isolation transistor is electrically connected to the isolation gate line, and a body terminal of the third isolation transistor is electrically connected to the third well region, wherein the first well line is electrically connected to the third well region.

12. The SONOS type non-volatile memory as claimed in claim 1, wherein when a program action is performed, an off voltage is provided to the isolation gate line, a program voltage is provided to the first well line and the second well line, a ground voltage is provided to the first bit line and the second bit line, a control voltage is provided to the control line, an on voltage is provided to a first word line of the plurality of word lines, the off voltage is provided to other word lines of the plurality of word lines, the program voltage is provided to the first source line, and the second source line is in a floating state, wherein a first SONOS memory cell in the first row generates a program current, and the program current flows from the first source line to the first bit line, so that the first SONOS memory cell is in a program state.

13. The SONOS type non-volatile memory as claimed in claim 1, wherein when an erase action is performed, an off voltage is provided to the isolation gate line, a positive voltage is provided to the first well line and the first source line, a ground voltage is provided to the second well line and the second source line, a negative voltage is provided to the control line, the off voltage is provided to the plurality of word lines, and the first bit line and the second bit line are in a floating state, wherein each of the plurality of SONOS memory cells in the first row is in an erase state, and a storage state of each of the plurality of SONOS memory cells in the second row is not changed, wherein a difference between the positive voltage and the negative voltage is an erase voltage.

14. The SONOS type non-volatile memory as claimed in claim 1, wherein when a read action is performed, an off voltage is provided to the isolation gate line, a read voltage is provided to the first well line and the second well line, the read voltage is provided to the first source line and the second source line, a ground voltage is provided to the first bit line and the second bit line, a control voltage is provided to the control line, an on voltage is provided to a first word line of the plurality of word lines, and the off voltage is provided to other word lines of the plurality of word lines, wherein a first read current generated by a first SONOS memory cell in the first row flows from the first source line to the first bit line, and a second read current generated by a second SONOS memory cell in the second row flows from the second source line to the second bit line, wherein a storage state of the first SONOS memory cell is determined according to a magnitude of the first read current, and a storage state of the second SONOS memory cell is determined according to a magnitude of the second read current.

15. The SONOS type non-volatile memory as claimed in claim 1, wherein the first bit line is electrically connected to the second bit line.
